(19) United States
(12) Patent Application Publication
(10) Pub. No.: US 2013/0028010 A1
(43) Pub. Date: Jan. 31, 2013

(54) Fast MTJ Switching Write Circuit For MRAM Array

(71) Applicants: Xia Li, San Diego, CA (US); Xiaochun Zhu, San Diego, CA (US); Wuyang Hao, San Diego, CA (US)

(72) Inventors: Xia Li, San Diego, CA (US); Xiaochun Zhu, San Diego, CA (US); Wuyang Hao, San Diego, CA (US)

(73) Assignee: QUALCOMM INCORPORATED, San Diego, CA (US)

(21) Appl. No.: 13/193,689

(22) Filed: Jul. 29, 2011

(51) Int. Cl. G11C 11/16

(52) U.S. Cl. 365/158

(57) ABSTRACT

A transmission gate is arranged between a current source and a resistive memory element, a PMOS gate of the transmission gate has no source loading effect and a write current passes from the current source, and in a first direction through the resistive memory element, setting the resistive memory element to a magnetization state. An NMOS gate of the of the transmission gate has no source loading effect and another write current, passes through the resistive memory element, in a second direction opposite the first direction, and through the transmission gate, setting the resistive memory element to an opposite magnetization state.

### FIELD OF DISCLOSURE

The present application relates to non-volatile resistive memories and, more particularly, to generation and control write currents to resistive memory elements of non-volatile resistance memories.

### BACKGROUND

Resistance-memories store “0” and “1” bits as discrete magnetization states of magnetic tunnel junction transistors (MTJs). The electrical resistance of an MTJ depends, to a detectable degree, on its magnetization state. This distinguishes from storing bits as electrical charge levels on capacitors, as done by conventional semi-conductor memory. MTJs do not require power to maintain their magnetization state and, therefore, may be referenced as non-volatile resistance (NVR) memory.

There are various NVR memory technologies, for example magnetoresistive random access memory (MRAM), spin-transfer torque MRAM (STT-MRAM) and others. NVR memory is seen as a promising option to meet projected data storage needs for a range of applications. Applications include personal computing devices, because NVR memories may offer high storage capacity while consuming considerably less power than conventional semiconductor memories. MTJs may also provide non-volatile storage estimated, in the general engineering literature, as extending to multiple decades.

Conventional read circuitry for an NVR bit cell injects a read current through a path controlled by switches to include the MTJ, and then detects difference in current or voltage between the MTJ and a reference circuit. Since the MTJ is in the path the voltage correlates to and, ideally, indicates the MTJ's resistance and, therefore, whether it is in a “0” or a “1” magnetization state.

Writing a “0” or “1” to an MTJ of a conventional NVR memory has some similarity to reading, where switches place the selected MTJ into a path but, instead of a read current, higher power is applied to push a write current through the MTJ. The write current level, which is significantly higher than the read current, is intended to set or change the magnetization state of the MTJ to that representing a “0” or “1” by current direction.

Conventional STT NVR memory write circuits generally include an NMOS transistor with each MTJ, and control the NMOS transistor with a word line (WL) to selectively place the MTJ into a path between a bit line and a source line. Power is applied to one of the bit line and the source line, and the other of the lines is coupled to ground.

In such conventional NVR memory write circuits, though, the write current can be limited, particularly for reverse writing, by constraints of the source loading body effect operating region of the NMOS WL transistor. For example, the conventional NVR STT memory's NMOS WL transistor has good forward gate-source bias only for a forward write current. The reverse write current is constrained to the source loading body effect of the NMOS WL transistor. As a result, increasing the NMOS WL transistor's width will not generally provide a useful return in additional drive current. Overdriving the NMOS WL transistor may not be a solution either. For example, the necessary high voltage may be unavailable. Also, even if available such overdriving may result in decreased reliability.

### SUMMARY

Exemplary embodiments of the invention are directed to systems and methods for writing resistive memory elements of an NVR STT memory.

One exemplary embodiment includes a resistive memory device comprising a resistive memory bit cell having a resistive memory element coupled to a bit line and a transmission gate configured to selectively couple the resistive memory element to a complement bit line. An example resistive memory device according to the one embodiment may have a write circuit having a constant current source, a complement bit line switch to selectively couple the constant current source to the complement bit line and a transmission gate control circuit to control the transmission gate.

In an aspect, the transmission gate may include an NMOS gate and a PMOS gate.

In an aspect the resistive memory element may include a spin-transfer-torque (STT) magnetic tunnel junction (MTJ) element.

One exemplary embodiment provides a method for setting a magnetization state of a resistive memory element, the method including forward switching on a transmission gate, injecting a forward write current through the resistive memory element and the transmission gate to set a forward magnetization state, and the method further including reverse switching on a transmission gate and injecting a reverse write current through the transmission gate and the resistive memory element to set a reverse magnetization state.

In an aspect according to one exemplary embodiment, forward switching on a transmission gate and injecting a forward write current includes source loading effect on PMOS pass gate. In a related aspect, forward switching on a transmission gate and injecting a forward write current is without source loading effect on an NMOS pass gate.

In another aspect according to one exemplary embodiment, reverse switching on a transmission gate includes source loading effect on NMOS pass gate. In a related aspect, reverse switching on a transmission gate and injecting a reverse write current is without source loading effect on a PMOS pass gate

One exemplary embodiment provides a communication device having an antenna, a wireless controller coupled to the antenna, and an integrated circuit coupled to the wireless controller. In an example communication device according to the one exemplary embodiment, the integrated circuit may include a processing unit, and a resistive memory coupled to the processing unit. Further in an example communication device according to one exemplary embodiment, the resistive memory may include a resistive memory element coupled to a bit line and a transmission gate configured to selectively couple the resistive memory element to a complement bit line, and may include a write circuit. In one example communication device according to one exemplary embodiment, the write circuit may have a constant current source, a complement bit line switch to selectively couple the constant current source to the complement bit line and a transmission gate control circuit to control the transmission gate.

One exemplary embodiment provides a method for setting a magnetization state of a resistive memory element, and the method may include a step of forward switching on a transmission gate, a step of injecting a forward write current through the resistive memory element and transmission gate, a step of reverse switching on a transmission gate, and a step of injecting a reverse write current through the transmission gate and the resistive memory element.

### BRIEF DESCRIPTION OF THE DRAWINGS

The accompanying drawings are presented to aid in the description of embodiments of the invention and are provided solely for illustration of the embodiments and not limitation thereof

FIG. 1 is a simplified schematic of a section of a transmission gate switched, constant current write NVR memory array according one or more exemplary embodiments.

FIG. 2 is a simplified schematic of a forward write path and a reverse write of an example transmission gate switched, constant current write NVR memory array according one or more exemplary embodiments.

FIG. 3 shows a forward write voltage versus forward write current and reverse write voltage versus reverse saturation limited write current through an NMOS switched MTJ write circuit.

FIG. 4 is a simplified schematic of one example constant current source for an NVR memory array with transmission gate-switched, constant current features according to one or more exemplary embodiments.

FIG. 5 is a simplified schematic of a section of a transmission gate switched, constant current bi-directional write NVR memory array according one or more exemplary embodiments.

FIG. 6 is a simplified schematic of a forward write path and a reverse write path of an example transmission gate switched, constant current bi-directional write NVR memory array according one or more exemplary embodiments.

FIG. 7 is a functional block diagram of one example personal computing device according to one or more exemplary embodiments.

FIG. 8 is a functional flow diagram of one process in fabricating an NVR memory embodying various aspects transmission gate switched, constant current write systems according one or more exemplary embodiments.

FIG. 9 is a functional block diagram of example personal computing devices according to one or more exemplary embodiments.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

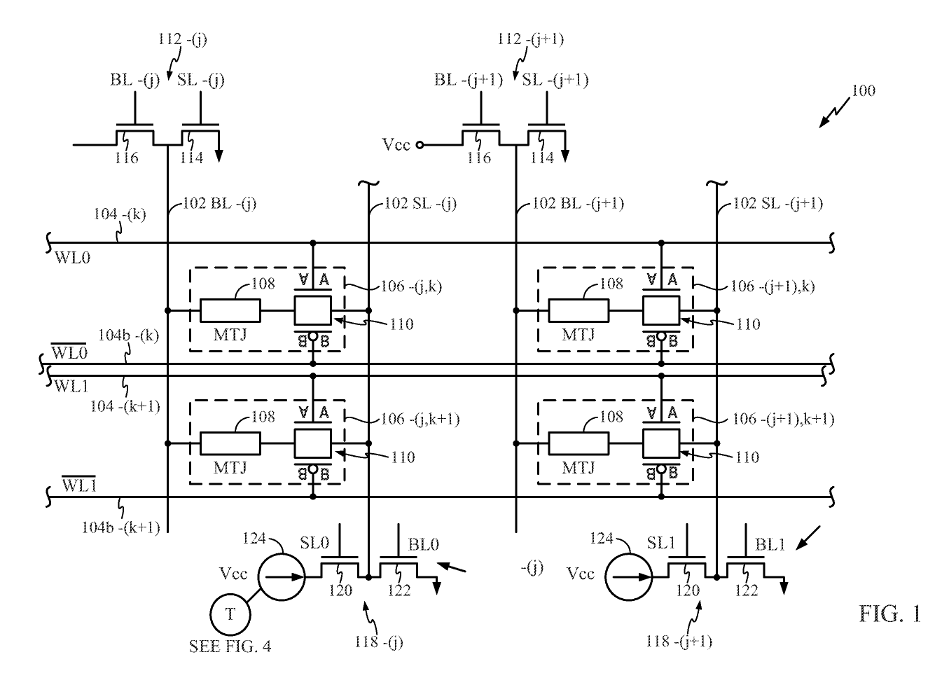

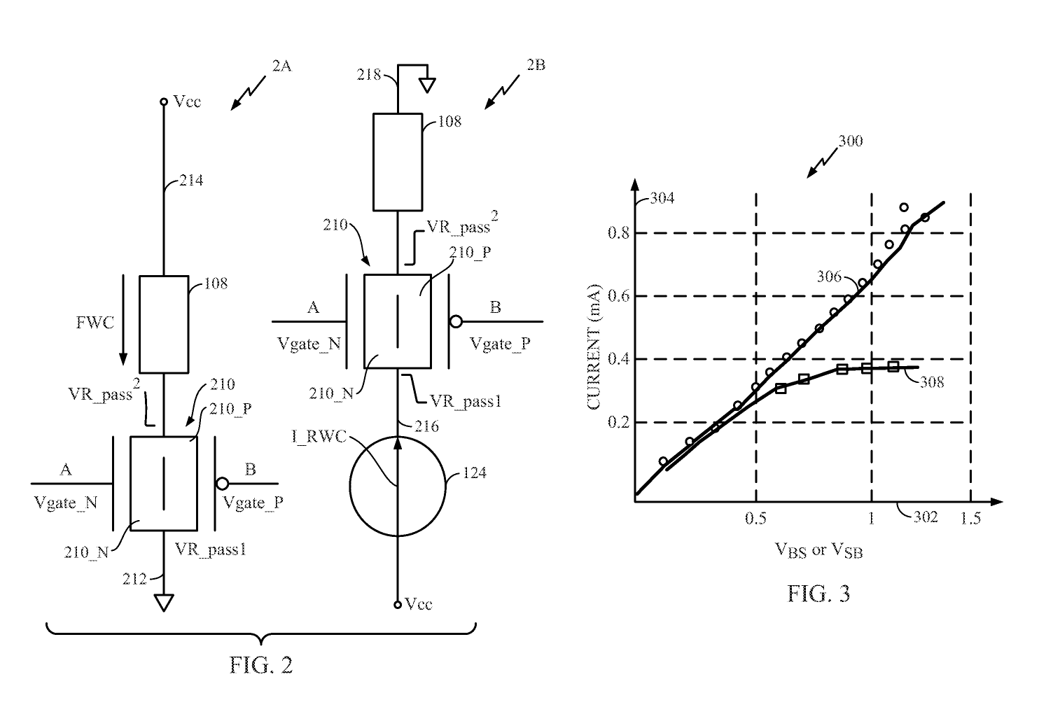

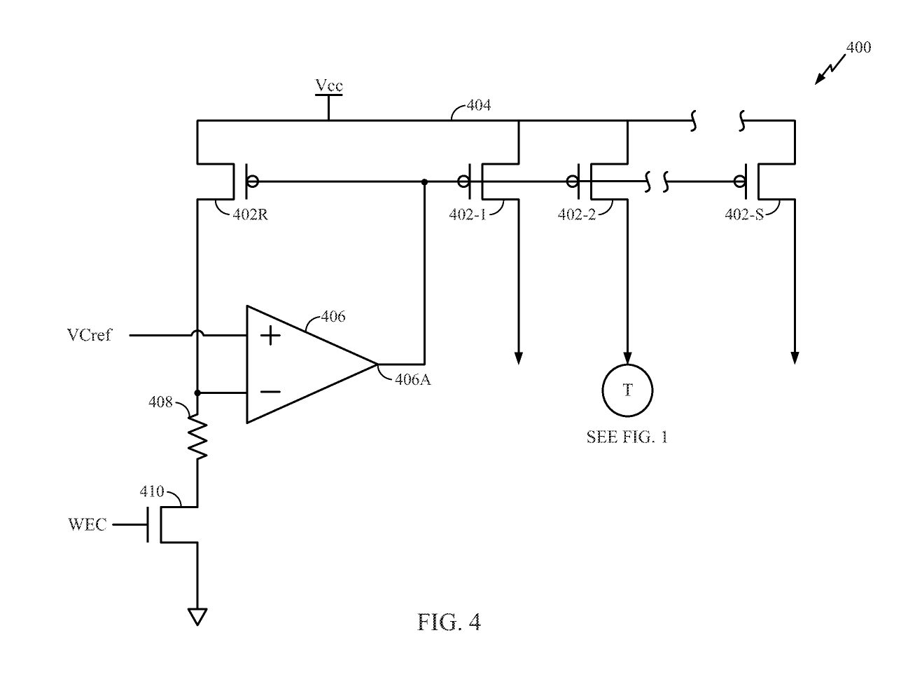

FIG. 1 shows a simplified schematic of a representative 2×2 section of one example transmission gate switched, constant current write NVR memory array 100, according to one or more exemplary embodiments. Referring to FIG. 1, the depicted section has two write complementary bit line pairs, one pair labeled 102BL-(j), and another pair labeled 102SL-(j) and 102BL-(j+1), 102SL-(j+1). These two write complementary bit line pairs may be representative of what may be M of such write complementary bit line pairs, are referenced generically as 102BL-x, 102SL-x and collectively as 102BL, 102SL. The 102BL lines may be referred to as “bit lines,” and their complement bit lines 102SL may also be referred to as “source lines.”

Referring still to FIG. 1, two complementary word line pairs are depicted, one labeled 104-(k), 104b-(k) and the other labeled 104-(k+1), 104b-(k+1). These two depicted complementary word line pairs may be representative of N of such complementary word line pairs, referenced generically as 104-y, 104b-y, and collectively as 104, 104b. In one aspect, the N complementary word line pairs 104, 104b and the M write complementary bit line pairs 102BL 102SL may form M×N intersections. To illustrate, for each write complementary bit pair 102BL-x, 102SL-x, for x=1 to M, there may be N intersections with a complementary word line pair, one for each of 104-y, 104b-y, for y=1 to N.

With continuing reference to FIG. 1, at each such intersection of a complementary bit line pair 102BL-x, 102SL-x, and a write complementary word line pair 104-y, 104b-y, an NVR bit cell 106(x, y) (generically 106) may be arranged. FIG. 1 illustrates four of these as NVR bit cells 106-(j,k), 106-(j+1, k), 106-(j, k+1) and 106-(j+1, k+1). Each NVR bit cell 106 may include an MTJ 108 in series with a corresponding transmission gate 110, with the MTJ 108 coupled to a bit line 102BL-x and the transmission gate 110 coupled to a the source line 102SL-x associated with the bit line 102BL-x. When the transmission gate 110 is switched ON a current path from the bit line 102BL-x to the source line 102SL-x is formed, through the transmission gate 110 and through the MTJ 108.

Referring still to FIG. 1, bit line 102BL-x may be coupled by a corresponding one of M bit line switches 112, referenced generically as 112-x, of which bit line switches 112-(j) and 112-(j+1) are representative, to one of Vcc or GND. Each bit line switch 112 may have a Vcc forward write switch 114 and a GND reverse write termination switch 116, to selectively couple the bit line 102BL-x to one of Vcc or GND, respectively. In one aspect, each source line 102SL-x may couple to a corresponding one of M complement bit line switches 118, referenced generically as 118-x, of which complement bit line switches 118-(j) and 118-(j+1) are representative. The complement bit line switches 118 may have a constant current reverse write switch 120 and a GND forward write termination switch 122, to selectively couple the source line 102SL-x to one of a reverse write constant current source 124 or GND.

Continuing to refer to FIG. 1, associated with each of the M write complementary bit line pairs 102BL-x, 102SL-x may be a write bit line control BL-x and a write complement bit line or write source line control SL-x, each coupled to both the bit line switch 112-x and the complement bit line switch 118-x. Further to one aspect, the write bit line control BL-x and the write source line control SL-x are configured so that their relative polarity, meaning which has a “1” voltage and which has a “0” voltage, controls the direction that a write current is pushed through the MTJ 108.

In the FIG. 1 example configuration of the bit line switches 112 and complement bit line switches 118, as can be readily appreciated by persons of ordinary skill in the art, when the transmission gate 110 of an NVR bit cell 106-(x, y) is enabled, a “1” voltage on the write bit line control BL-x and corresponding “0” voltage on the complementary source line control SL-x, switch the bit line switch 112-x and the complement bit line switch 118-x to couple Vcc to the bit line 102BL-x and to couple the source line 102SL-x to a ground rail (not separately shown). WL-y (Word line y) is a setup “1” voltage and complement WL-y is a setup “0” voltage to turn on the transmission gate 110. This pushes a forward write current through the MTJ 108 of that NVT bit cell (x, y). As shown, the WL-y and the complement WL-y of the FIG. 1 example serve as a transmission gate control circuit for the transmission gate 110.

On the other hand, referring still to FIG. 1, when a “0” voltage is on the write bit line control BL-x and a “1” voltage is on the source line control SL-x, the complement bit line switch 118-x couples a reverse write constant current source 124 to the source line 102SL-x, and the bit line switch 112-x couples the bit line 102BL-x to GND. In this state, when the transmission gate 110 of an NVR bit cell 106-(x, y) the reverse write constant current source 124 pushes a reverse write current into the source line 102SL-x, through the MTJ 108 of the NVT bit cell 106-(x, y), to the bit line 102BL-x and to GND.

It will be understood that read circuitry is not depicted in FIG. 1. As can be readily seen by persons of ordinary skill in the art, the transmission gates 110 may be used for read access and, the remaining read circuitry and read methods may be according to conventional means, not specific to the embodiments. As also readily seen by such persons a separate, conventional read access transistor, e.g., an NMOS transistor (not shown) parallel to the transmission gate 110, may be included, along with conventional read circuitry and read methods. Further detailed description is therefore omitted.

To illustrate concepts according to the exemplary embodiments, an example forward write and an example of reverse write to the MTJ 108 of the NVR bit cell 106-(j,k) will be described. To provide consistent reference between described example processes and the particular FIG. 1 structure, the example writes will label as “forward” the writes in which the write current goes through the MTJ 108 in the direction from the bit line (e.g., 102BL-(j)) to the source line (e.g., 102SL-(j)), and as “reverse” the writes in which the write current passes in the reverse direction. Also for consistent reference, it will be assumed that the forward write sets the MTJ 108 to a magnetization state representing a “1,” and the reverse write sets the MTJ 108 to a magnetization state representing a “0.”

Referring to FIG. 1, an example write to the NVR bit cell 106-(j,k), either forward or reverse, may begin by applying a word line voltage WL and its complement WL_b to the complementary word line pair 104-(k), 104b-(k). The specific WL voltage may depend on the technology chosen for the transmission gate 110, the available main rail voltage and other factors readily identified and understood by persons of ordinary skill in the art having this disclosure. Means for generating the complementary word line pair 104-(k), 104b-(k) are not explicitly shown, but may be based, for example, on a multi-bit address (not shown) provided to a conventional memory array address-row decoding circuit, appropriately modified to generate complementary word line pairs.

The applied WL/WL_b voltage is coupled through the complementary word line pair 104-(k), 104b-(k) to the complementary terminals 110A and 110B of the transmission gate 110 of the NVR bit cell 106-(j,k). The transmission gate 110 and MTJ 108 of the NVR bit cell 106-(j,k) then become a current path between the bit line 102BL-(j) and the source line 102SL-(j).

It will be understood that the complementary word line pair 104-(k), 104b-(k) also couples to the complementary terminals of the transmission gate 110 of every other NVR bit cell 106 in the same row as 106-(j,k). However, since a write operation applies a write current, as described below, to only one of the bit line pairs 102BL, 102SL, in this instance 102BL-(j) and 102SL-(j), the write operation will affect only the NVR bit cell 106-(j,k).

Continuing with the example forward write, the word enabling voltage WL/WL_b may be maintained on the complementary word line pair 104-(k), 104b-(k) over a given time interval, referenced hereinafter as WE_INV. Over a time interval overlapping WE_INV a “1” voltage is applied to the write bit line control BL-j and corresponding “0” voltage to the complementary write source line control SL-(j). The BL-(j) value of “1” switches ON the forward write current switch 114 of the bit line switch 112-(j) and switches ON the GND forward write termination switch 122 of the complement bit line switch 118-(j). The SL-(j) value of “0” switches OFF the GND reverse write termination switch 116 of the bit line switch 112-(j) and switches OFF the constant current reverse write switch 120 of the complement bit line switch 118-(j). Vcc is now coupled to the bit line 102BL-(j), while the source line 102SL-(j) is coupled to ground. Vcc pushes a forward write current, shown as FWC in FIG. 2 described below, through the MTJ 108. The magnitude of FWC is determined by Vcc and the resistance of the forward write current path, i.e., the resistance of the MTJ 108 added to the resistance of the forward write switch 114 of the bit line switch 112-(j), and the resistance of the forward write termination switch 122 of the complement bit line switch 118-(j), and the resistance of the transmission gate 110 and all other devices in the current path.

FIG. 2 shows a simplified schematic 2A of the above-described forward write current path carrying the forward write current FWC. The path segment 214 represents the forward write switch 114 of the bit line switch 112-(j) and the length of the write bit line 102BL-(j) extending to the NVR bit cell 106-(j,k). The path segment 212 represents the length of the bit line 102BL-(j) extending from the transmission gate 110 to the complement bit line switch 118-(j), and the forward write termination switch 122. The transmission gate 110 is shown in further detail as an NMOS gate or device 210_N, functioning as a forward pass gate, in parallel with a PMOS gate or device 210_P, functioning as a reverse pass gate.

As will be described in greater detail at later sections, in the forward write current path represented by the simplified schematic 2A shown in FIG. 2, the transmission gate 110 is in what may be termed a “forward on state,” in which NMOS device 210_N is forward biased, and the PMOS device 210_P body is reverse biased and therefore has only a body effect. However, in the forward on state the PMOS device 210_P does not operate as a current limiter for the forward write current through the MTJ 108, because the forward biased NMOS device 210_N provides a low-resistance path.

It will be understood that the order of describing the generating of the word line enable voltage WL, the bit values and complement bit values BL-x and SL-x is in an order for clear description of concepts, without unnecessary complexity not relevant to understating such concepts, and may not limit the order, or other relative timings of signal, current and voltage generation for practicing according to the exemplary embodiments.

Next, an example “reverse” write to the MTJ 108 of the NVR bit cell 106-(j,k) of the FIG. 1 example transmission gate switched, constant current write NVR memory array 100 will be described. The reverse write may begin by applying, just as previously described for a forward write, a word line enabling voltage WL/WL_b to the complementary word line pair 104-(k), 104b-(k). The applied WL/WL_b voltage is coupled through the complementary word line pair 104-(k), 104b-(k) to the transmission gate 110 of the NVR bit cell 106-(j,k), causing the MTJ 108 and transmission gate 110 to become a current path between the bit line 102BL-(j) and source line 102SL-(j). As previously described, the duration may be referenced as WE_INV.

Continuing with description of an example reverse write, over a time interval overlapping WE_INV a “0” voltage is applied to the write bit line control BL-(j) and corresponding “1” voltage is applied to the write source line control SL-(j). The BL-(j) of “0” switches OFF the forward write switch 114 of the bit line switch 112-(j) and switches OFF the GND forward write termination switch 122 of the complement bit line switch 118-(j). The SL-(j) of “1” switches ON the GND reverse write termination switch 116 of the bit line switch 112-(j) and switches ON the constant current reverse write switch 120 of the complement bit line switch 118-(j). The write constant current source 124 is then coupled to the source line 102SL-(j), while the bit line 102BL-(j) is coupled to GND. The reverse write constant current source 124 is then able to push a reverse write current, shown as I_RWC in the simplified schematic 2B of FIG. 2, through the MTJ 108, to GND. As described below in reference to FIG. 2, a significant feature of the exemplary embodiments is that, in a reverse write, the PMOS device 210_P of the transmission gate 210, which is representative of the transmission gate 110 shown in FIG. 1, is forward biased and functions as the primary access for the reverse write current to flow through the MTJ. This may be termed a “reverse on” state of the FIG. 1 transmission gate 110.

Referring to FIG. 2, the simplified schematic 2B represents the above-described reverse write current path, and the flow of the reverse write current I_RWC injected by the reverse write constant current source 124. The path segment 216 represents the constant current reverse write switch 120 coupled to the reverse write constant current source 124 the length of the write source line 102SL-(j) extending to the NVR bit cell 106-(j, k). The path segment 218 represents the length of the write bit line 102BL-(j) extending from the MTJ 108 to the bit line switch 112-(j) and its GND reverse write termination switch 116.

Referring still to FIG. 2, the voltage “Vgate_N” represents the voltage WL applied by the word line 104-(k) to the NMOS device 210_N of the transmission gate 110. The voltage “Vgate_P” represents the voltage WL_b applied by the complementary word line 104b-(k) to the PMOS device 210_P of the transmission gate 110. The voltage “VR_pass1” represents the voltage at the output of the reverse constant current source 124, and the voltage “VR_pass2” represents the voltage at the reverse current output of the transmission gate 110. It will be understood that considering reverse write resistances exhibited by MTJs that may implement the MTJ 108, and Vcc values that may be employed in practicing the exemplary embodiments, there may be only a small voltage drop across the constant current source 124. Therefore, VR_pass1 may be not significantly lower than the Vcc value. The NMOS device 210_N of the transmission gate 110 may therefore be reverse biased. If the NMOS device 210_N of the transmission gate 110 were a stand-alone device, such a value of VR_pass2 relative to GND would cause that NMOS device 210_N to have body effect and increased threshold voltage, presenting a substantial, resistance to the constant current source 124. It will be understood that significant design accommodation, such as a specially fabricated structure for that NMOS half, or voltage boost to significantly overdrive the NMOS device 210_N, this source loading resistance might severely limit the reverse write current. The limitation could be such that the reverse write performance may be less than optimal, or unacceptable. Conventional NVR voltage source reverse write circuitry may inherently possess such shortcomings and, therefore, may necessitate various design accommodations and performance trade-offs.

The FIG. 3 NMOS source line to bit line (or vice versa) voltage versus current characteristic 300 further illustrates this shortcoming of NMOS switched NVR write current circuits by constant voltage driver. Referring to FIGS. 2 and 3 together, the FIG. 3 axis 302 is the voltage across the NMOS device and MTJ, e.g., the difference between the FIG. 2 Vcc to GND if employing only the NMOS device 210_N of the transmission gate 110, i.e., an NMOS device for reverse write access to the MTJ 108. The axis 304 is the current through such an NMOS switch device 210_N in such an arrangement. The forward bias characteristic V-I line 306 is the voltage-current characteristic of the NMOS device 210_N during a forward write operation, in a forward write state as represented by the FIG. 2 simplified schematic 2A. As readily seen, in this forward write circuit state the voltage VR_pass1 is at GND, while the WL voltage (which may be Vcc) is applied to the gate (not separately numbered) of the NMOS device 210_N. The gate-source voltage of the NMOS device 210_N is therefore forward biased, wherein it acts as a linear resistor. This is shown by the forward bias characteristic V-I line 306.

Continuing in reference to FIGS. 2 and 3, in the reverse write state shown by the FIG. 2 simplified schematic 2B, VR_pass2 of the NMOS device 210_N is no longer at GND. Instead, VR_pass2 is the voltage of MTJ 108. This voltage is higher than GND and, in fact, may be lower than the drain and gate voltage to source of NMOS device 210_N. The NMOS device 210_N therefore has reverse body to source voltage, which causes the NMOS device 210_N threshold voltage to increase. The result is the reverse bias characteristic shown as the V-I line 308. As readily seen, the NMOS device 210_N in the reverse write state represented by the FIG. 2 simplified schematic 2B may saturate at a source line-bit line voltage of, for example, approximately 0.5 V. When the NMOS device 210_N is in such a saturation state then, as illustrated by the reverse bias characteristic V-I line 308, the current through the device may not increase appreciably regardless of the voltage applied by the constant voltage Vcc. In other words, the constant voltage Vcc may be rendered ineffective.

Therefore, it will be appreciated that among various features and benefits of constant current source 124 and a transmission gate switched, constant current write NVR memory array of the exemplary embodiments, the arrangement of transmission gates 110 overcomes shortcomings of conventional NMOS switched, constant Vcc NVR write circuits. For example in a forward writing, as shown by the FIG. 2 simplified schematic 2A, the NMOS device 210_N of the transmission gate 110 acts as the primary access device, and this providing a fast-switching, low-resistance path for the forward write current to pass through the MTJ 108. During this forward write the PMOS device 210_P of the transmission gate 110, although having a reverse bias body effect that standing alone would significantly resist the forward write current, is rendered irrelevant. Further, in reverse writing, as shown by the FIG. 2 simplified schematic 2B, the PMOS device 210_P of the transmission gate 110 now acts as the primary access device, providing a fast switching, low-resistance path for the reverse write current to pass through the MTJ 108. The reverse-bias of the NMOS device 210_N is therefore rendered irrelevant.

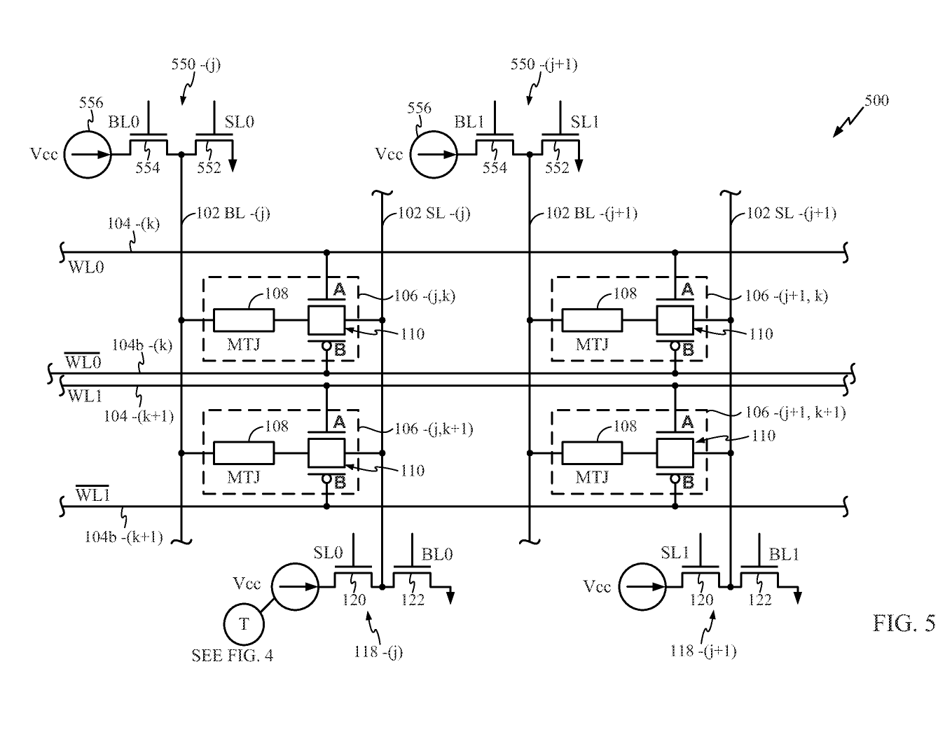

FIG. 4 shows a simplified schematic of one example current source 400 that may implement one or more of the constant write current sources 124 in a transmission gate-switched, constant write current NVR memory array according to exemplary embodiments. Referring to FIG. 4, the example constant current source 400 may comprise a feedback current minor 402R and a plurality of S write current valves 402-1, 402-2 . . . 402-S, referenced collectively as 402 and generically as 402-x, which may be PFETs, coupled between a Vcc rail 404 and a feedback “−” input of a voltage sense amplifier 406. The FIG. 4 example further includes a current reference resistor 408, having a given value R_reverse, also coupling that feedback “−” input of the voltage sense amplifier 406 to ground, through an enabling switch 410. The enabling switch 410 may receive a write current enable signal WEC. The “+” input of the voltage sense amplifier 406 receives a current level control signal VCref. The output 406A of the voltage sense amplifier 406 couples to the control input (depicted but not separately numbered) of the feedback current mirror 402R, and to the control input (depicted but not separately numbered) of each of the S write current valves 402. Each write current valve 402-x may be coupled at one end to the Vcc power rail 404 and coupled at its other end to, for example, the constant current write switch 120 in the FIG. 1 example complement bit line switch 118-x.

FIG. 5 shows a simplified schematic of a representative 2×2 section of one example transmission gate switched bi-directional constant current NVR memory array 500, according to various exemplary embodiments. The FIG. 5 example transmission gate switched bi-directional constant current NVR memory array 500 may be implemented similar to an implementation of the FIG. 1 transmission gate switched, constant current NVR memory array 100. To avoid unnecessary complexity in the description, and particularly describe concepts of this FIG. 5 embodiment, structures and control signals that may, for illustration, be common to the FIG. 1 embodiments are labeled with like numbering.

Referring to FIG. 5, the example four NVR bit cells 106-(j,k), 106-(j+1, k), 106-(j, k+1) and 106-(j+1, k+1) each have the following arrangement, as previously described: an MTJ 108 in series with a transmission gate 110, the MTJ 108 coupled to a bit line 102BL-x and the transmission gate 110 coupled to a corresponding source line 102SL-x associated with the bit line 102BL-x. In one aspect, as described in reference to FIG. 1, one end of each source line 102SL-x may couple to a corresponding one of M complement bit line switches 118, of which complement bit line switches 118-(j) and 118-(j+1) are representative. The complement bit line switches 118 may have a constant current reverse write switch 120 and a GND forward write termination switch 122, to selectively couple that one end of the source line 102SL-x to one of a reverse write constant current source 124 or GND.

Referring still to FIG. 5, each bit line 102BL-x may, however, couple to a corresponding one of M bit line switches 550-x, for x=1 to M, in a manner as represented by the bit line switches 550-(j) and 550-(j+1). Each bit line switch 550-x may have an associated bit line forward write current switch 552 and bit line reverse write termination switch 554. The bit line forward current switch 552 selectively couples, for performing a forward write to any of the M NVR bit cells 106(x,y) coupled to the complementary bit line pair 102BL-x, 102SL-x, the bit line 102BL-x to a write constant current source 556.

An example forward write to the MTJ 108 of the NVR bit cell 106-(j,k) will be described. The forward write may begin by applying the word enabling voltage WL/WL_b to the complementary word line pair 104-(k), 104b-(k). The applied WL/WL_b voltage is coupled through the complementary word line pair 104-(k), 104b-(k) to the complementary terminals of the transmission gate 110 of the NVR bit cell 106-(j,k). As previously described, the series arrangement of the transmission gate 110 and the MTJ 108 of the NVR bit cell 106-(j,k) then become a current path between the bit line 102BL-(j) and the source line 102SL-(j).

Continuing with the example forward write, over a time overlapping with the transmission gate 110 being switched on by WE_INV, a “1” voltage is applied to the write bit line control BL-(j) and corresponding “0” voltage to the complementary write source line control SL-(j). The BL-(j) of “1” switches ON the bit line forward write current switch 552 of the bit line switch 550-(j), and switches ON the GND forward write termination switch 122 of the complement bit line switch 118-(j). The SL-(j) of “0” switches OFF the bit line reverse write termination switch 554 of the bit line switch 550-(j), and switches OFF the bit line reverse write current switch 120 of the complement bit line switch 118-(j).

The result of the above-described “1” on the write bit control line BL-(j) and corresponding “0” voltage to the complementary write source line control SL-(j) is that the forward write constant current source 556 is coupled to the bit line 102BL-(j), and the source line 102SL-(j) is coupled to ground. The forward write constant current source 556 then injects a forward write current I_FWD into the bit line 102BL-(j), current flows through the MTJ 108, through the transmission gate 110, to source line 102SL-(j), and then to ground through the forward write termination switch 122 of the complement bit line switch 118-(j). The injection of the forward write current I_FWD may provide improved write performance by constant current source.

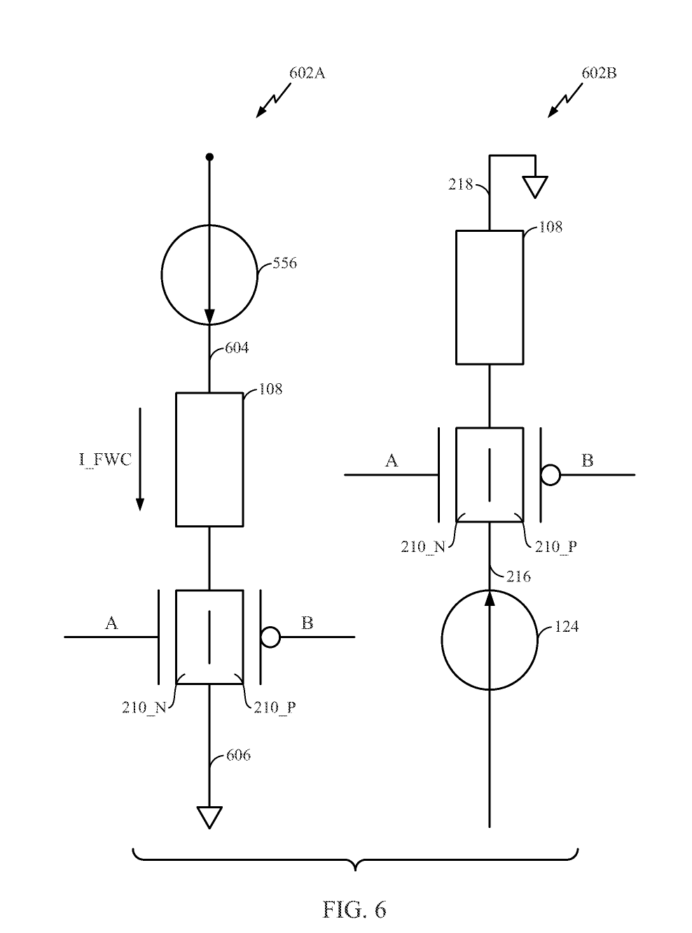

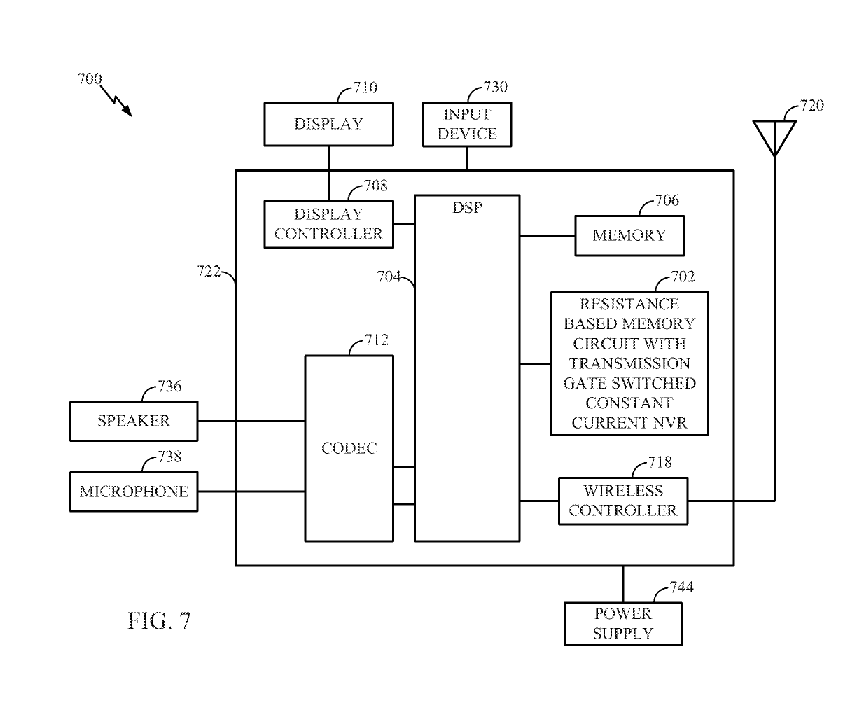

Referring to FIG. 6, 602A is a simplified schematic of a forward constant write circuit state having the above-described forward write current path. As depicted, the forward constant write current I_FWC being injected by the write constant current source 556, through a path segment 604, to the MTJ 108, through the transmission gate 110, then through a path segment 606 to GND. The path segment 604 represents the bit line switch 550-(j), and the length of the write bit line 102BL-(j) extending to the NVR bit cell 106-(j,k). The path segment 606 represents the length of the bit line 102BL-(j) extending from the transmission gate 110 to the complement bit line switch 118-(j), and the forward write termination switch 122.

With respect to a reverse write to the MTJ 108 of the NVR bit cell 106-(j,k), this may be performed by the FIG. 5 transmission gate switched bi-directional constant current NVR memory array 500 in accordance with the reverse write described in reference to FIG. 1, using the GND reverse write termination switch 554 in place of the GND reverse write termination switch 116. The resulting reverse write current path is shown by the FIG. 6 simplified schematic 602B, which may be identical to the FIG. 2 simplified schematic 2B.

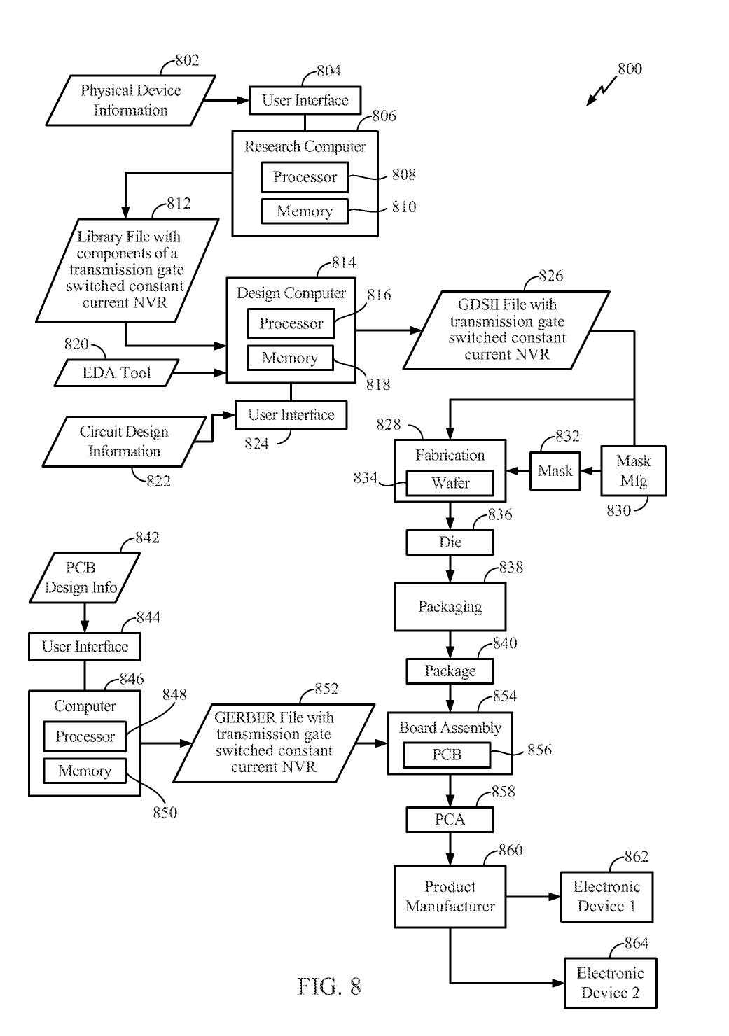

FIG. 7 is a functional block diagram of an electronic device 700, such as a wireless phone according to one or more exemplary embodiments. The device 700 may include a transmission gate switched, constant current write NVR memory circuit 702 coupled to a processor such as a digital signal processor (DSP) 704 that may be coupled to another memory 706, for example a DRAM. In one illustrative example, the transmission gate switched, constant current write NVR memory circuit 702 may include the apparatus such as the transmission gate switched, constant current write NVR memory array 100 described in reference to FIG. 1, or as one alternative, the transmission gate switched bi-directional constant current write NVR memory array 500 described in reference to FIG. 5 or, in alternative, any combination thereof.

Referring still to FIG. 7, the electronic device 700 may have a display controller 708 coupled to the DSP 704 and to a display 710. In addition, a coder/decoder (CODEC) 712 may be coupled to the DSP 704, and to a speaker 736 and a microphone 738. A wireless controller 718 may be coupled to the digital signal processor 704 and to a wireless antenna 720. In a particular embodiment, the DSP 704, the display controller 708, the transmission gate switched, constant current write NVR memory circuit 702, and the CODEC 712, and the wireless controller 718 are included in a system-in-package or system-on-chip (SOC) 722. In a particular embodiment, an input device 730 and a power supply 744 are coupled to the SOC 722. Moreover, as illustrated in FIG. 7, in one aspect the display 710, the input device 730, the speaker 736, the microphone 738, the wireless antenna 720, and the power supply 744 may be external to the SOC 722. However, each may be coupled to one or more components of the SOC 722, for example through an interface or a controller.

The foregoing disclosed devices and functionalities may be designed and configured into computer files (e.g. RTL, GDSII, GERBER, etc.) stored on computer readable media. Some or all such files may be provided to fabrication handlers who fabricate devices based on such files. Resulting products include semiconductor wafers that are then cut into semiconductor die and packaged into a semiconductor chip. The chips are then employed in devices described above.

FIG. 8 depicts a particular illustrative embodiment of an electronic device manufacturing process 800. Physical device information 802 may be received in the manufacturing process 800, such as at a research computer 806. The physical device information 802 may include design information representing at least one physical property of a selective coupled/isolatable resistance based memory such as the transmission gate switched, constant current write NVR memory array 100 described in reference to FIG. 1, or as one alternative, the transmission gate switched bi-directional constant current write NVR memory array 500 described in reference to FIG. 5 or, in one alternative, any combination. For example, the physical device information 802 may include physical parameters, material characteristics, and structure information that may be entered via a user interface 804 coupled to the research computer 806. The research computer 806 may include a processor 808, such as one or more processing cores, coupled to a computer readable medium such as a memory 810. The memory 810 may store computer readable instructions that are executable to cause the processor 808 to transform the physical device information 802 to comply with a file format and to generate a library file 812.

In a particular embodiment, the library file 812 may include at least one data file including the transformed design information. For example, the library file 812 may include a library of semiconductor devices including any device(s) of the transmission gate switched, constant current write NVR memory array 100 described in reference to FIG. 1, or as one alternative, the transmission gate switched bi-directional constant current write NVR memory array 500 described in reference to FIG. 5 or, in one alternative, any combination thereof that is provided for use with an electronic design automation (EDA) tool 820.

The library file 812 may be used in conjunction with the EDA tool 820 at a design computer 814 including a processor 816, such as one or more processing cores, coupled to a memory 818. The EDA tool 820 may be stored as processor executable instructions at the memory 818 to enable a user of the design computer 814 to design a circuit including the transmission gate switched, constant current write NVR memory array 100 described in reference to FIG. 1, or as one alternative, the transmission gate switched bi-directional constant current write NVR memory array 500 described in reference to FIG. 5 or, in one alternative, any combination thereof, from the library file 812. For example, a user of the design computer 814 may enter circuit design information 822 via a user interface 824 coupled to the design computer 814. The circuit design information 822 may include design information representing at least one physical property of the transmission gate switched, constant current write NVR memory array 100 described in reference to FIG. 1, or as one alternative, the transmission gate switched bi-directional constant current write NVR memory array 500 described in reference to FIG. 5 or, in one alternative, any combination thereof. To illustrate, the circuit design property may include identification of particular circuits and relationships to other elements in a circuit design, positioning information, feature size information, interconnection information, or other information representing a physical property of a semiconductor device.

The design computer 814 may be configured to transform the design information, including the circuit design information 822 to comply with a file format. To illustrate, the file formation may include a database binary file format representing planar geometric shapes, text labels, and other information about a circuit layout in a hierarchical format, such as a Graphic Data System (GDSII) file format. The design computer 814 may be configured to generate a data file including the transformed design information, such as a GDSII file 826 that includes the transmission gate switched, constant current write NVR memory array 100 described in reference to FIG. 1, or as one alternative, the transmission gate switched bi-directional constant current write NVR memory array 500 described in reference to FIG. 5 or any combination thereof, in addition to other circuits or information. To illustrate, the data file may include information corresponding to a system-on-chip (SOC) that includes the SOC 722 of the electronic device 700 of FIG. 7 and that also includes additional electronic circuits and components within the SOC 722.

The GDSII file 826 may be received at a fabrication process 828 to manufacture the transmission gate switched, constant current write NVR memory array 100 described in reference to FIG. 1, or as one alternative, the transmission gate switched bi-directional constant current write NVR memory array 500 described in reference to FIG. 5 or, in one alternative, any combination thereof, according to transformed information in the GDSII file 826. For example, a device manufacture process may include providing the GDSII file 826 to a mask manufacturer 830 to create one or more masks, such as masks to be used for photolithography processing, illustrated as a representative mask 832. The mask 832 may be used during the fabrication process to generate one or more wafers 834, which may be tested and separated into dies, such as a representative die 836. The die 836 may include a circuit having one or more devices of the transmission gate switched, constant current write NVR memory array 100 described in reference to FIG. 1, or as one alternative, the transmission gate switched bi-directional constant current write NVR memory array 500 described in reference to FIG. 5 or, in one alternative, any combination thereof.

The die 836 may be provided to a packaging process 838 where the die 836 is incorporated into a representative package 840. For example, the package 840 may include the single die 836 or multiple dies, such as a system-in-package (SiP) arrangement. The package 840 may be configured to conform to one or more standards or specifications, such as Joint Electron Device Engineering Council (JEDEC) standards.

Information regarding the package 840 may be distributed to various product designers, such as via a component library stored at a computer 846. The computer 846 may include a processor 848, such as one or more processing cores coupled to a memory 850. A printed circuit board (PCB) tool may be stored as processor executable instructions at the memory 850 to process PCB design information 842 received from a user of the computer 846 via a user interface 844. The PCB design information 842 may include physical positioning information of a packaged semiconductor device on a circuit board, the packaged semiconductor device corresponding to the package 840 for the transmission gate switched, constant current write NVR memory array 100 described in reference to FIG. 1, or as one alternative, the transmission gate switched bi-directional constant current write NVR memory array 500 described in reference to FIG. 5 or, in one alternative, any combination thereof.

The computer 846 may be configured to transform the PCB design information 842 to generate a data file, such as a GERBER file 852 with data that includes physical positioning information of a packaged semiconductor device on a circuit board, as well as layout of electrical connections such as traces and vias, where the packaged semiconductor device corresponds to the package 840 including the device components to be used in the transmission gate switched, constant current write NVR memory array 100 described in reference to FIG. 1, or as one alternative, the transmission gate switched bi-directional constant current write NVR memory array 500 described in reference to FIG. 5 or, in one alternative, any combination thereof In other embodiments, the data file generated by the transformed PCB design information may have a format other than a GERBER format.

The GERBER file 852 may be received at a board assembly process 854 and used to create PCBs, such as a representative PCB 856, manufactured in accordance with the design information stored within the GERBER file 852. For example, the GERBER file 852 may be uploaded to one or more machines for performing various steps of a PCB production process. The PCB 856 may be populated with electronic components including the package 840 to form a represented printed circuit assembly (PCA) 858.

The PCA 858 may be received at a product manufacture process 860 and integrated into one or more electronic devices, such as a first representative electronic device 862 and a second representative electronic device 864. As an illustrative, non-limiting example, the first representative electronic device 862, the second representative electronic device 864, or both, may be selected from the group of a set top box, a music player, a video player, an entertainment unit, a navigation device, a communications device, a personal digital assistant (PDA), a fixed location data unit, and a computer. As another illustrative, non-limiting example, one or more of the electronic devices 862 and 864 may be remote units such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 7 may illustrate remote units according to the teachings of the disclosure, the disclosure is not limited to these exemplary illustrated units. Embodiments of the disclosure may be suitably employed in any device that includes active integrated circuitry including memory and on-chip circuitry for test and characterization. Thus, the transmission gate switched, constant current write NVR memory array 100 described in reference to FIG. 1, or as one alternative, the transmission gate switched bi-directional constant current write NVR memory array 500 described in reference to FIG. 5 or any combination thereof, may be fabricated, processed, and incorporated into an electronic device, as described in the illustrative process 800. One or more aspects of the embodiments disclosed with respect to FIGS. 1-6 may be included at various processing stages, such as within the library file 812, the GDSII file 826, and the GERBER file 852, as well as stored at the memory 810 of the research computer 806, the memory 818 of the design computer 814, the memory 850 of the computer 846, the memory of one or more other computers or processors (not shown) used at the various stages, such as at the board assembly process 854, and also incorporated into one or more other physical embodiments such as the mask 832, the die 836, the package 840, the PCA 858, other products such as prototype circuits or devices (not shown), or any combination thereof Although various representative stages of production from a physical device design to a final product are depicted, in other embodiments fewer stages may be used or additional stages may be included. Similarly, the process 800 may be performed by a single entity, or by one or more entities performing various stages of the process 800.

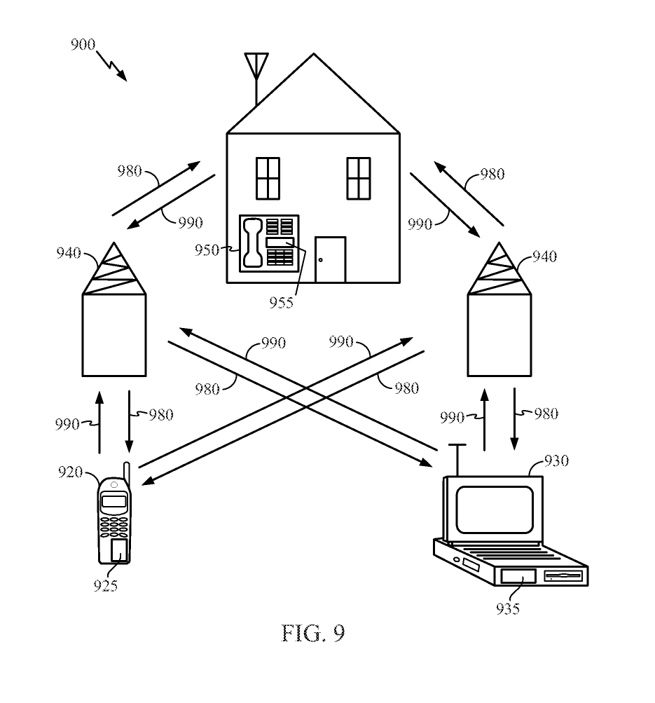

FIG. 9 illustrates an exemplary wireless communication system 900 in which one or more embodiments of the disclosure may be advantageously employed. For purposes of illustration, FIG. 9 shows three remote units 920, 930, and 950 and two base stations 940. It will be recognized that conventional wireless communication systems may have many more remote units and base stations. The remote units 920, 930, and 950 include semiconductor devices 925, 935 and 955 (including on-chip voltage regulators, as disclosed herein), which are among embodiments of the disclosure as discussed further below. FIG. 9 shows forward link signals 980 from the base stations 940 and the remote units 920, 930, and 950 and reverse link signals 990 from the remote units 920, 930, and 950 to the base stations 940.

In FIG. 9, the remote unit 920 is shown as a mobile telephone, the remote unit 930 is shown as a portable computer, and the remote unit 950 is shown as a fixed location remote unit in a wireless local loop system. For example, the remote units may be mobile phones, hand-held personal communication systems (PCS) units, portable data units such as personal data assistants, navigation devices (such as GPS enabled devices), set top boxes, music players, video players, entertainment units, fixed location data units such as meter reading equipment, or any other device that stores or retrieves data or computer instructions, or any combination thereof. Although FIG. 9 illustrates remote units according to the teachings of the disclosure, the disclosure is not limited to these exemplary illustrated units. Embodiments of the disclosure may be suitably employed in any device which includes active integrated circuitry including memory and on-chip circuitry for test and characterization.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for performing a write to an NVR memory in accordance with any forward write or any reverse write described, for example, in reference to any of FIGS. 1-6. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A resistive memory device, comprising:
a resistive memory bit cell having a resistive memory element coupled to a bit line and a transmission gate configured to selectively couple the resistive memory element to a complement bit line; and
a write circuit having a constant current source, a complement bit line switch to selectively couple the constant current source to the complement bit line and a transmission gate control circuit to control the transmission gate.

2. The resistive memory device of claim 1, wherein the write circuit further comprises a bit line switch configured to selectively couple the bit line to a ground rail.

3. The resistive memory device of claim 1, wherein the transmission gate includes a CMOS device having an NMOS gate in parallel with a PMOS gate.

4. The resistive memory device of claim 3, wherein the resistive memory element includes a spin-transfer-torque (STT) magnetic tunnel junction (MTJ) element.

5. The resistive memory device of claim 3, wherein the write circuit further comprises a bit line switch configured to selectively couple the bit line to a ground rail.

6. The memory device of claim 5, wherein the write circuit is configured to control the complement bit line switch, the PMOS gate and the bit line switch, respectively, to couple the complement bit line to the constant current source while the PMOS gate is in an ON state and the bit line is coupled to the ground rail.

7. The resistive memory device of claim 6, wherein the resistive memory element and the current source are arranged such when the complement bit line is coupled to the constant current source while the PMOS gate is in an ON state and the bit line is coupled to the ground rail the constant current source injects a reverse write current through the complement bit line switch, through the transmission gate, through the resistive memory element and through the bit line switch to ground.

8. The resistive memory device of claim 7, wherein the resistive memory element has a first magnetization state and a second magnetization state, and wherein the reverse write current places the resistive memory element into one of the first magnetization state and the second magnetization state.

9. The resistive memory device of claim 8, wherein the resistive memory element includes a spin-transfer-torque (STT) magnetic tunnel junction (MTJ) element.

10. The resistive memory device of claim 5, wherein bit line switch is further configured to selectively couple the bit line to a power rail and the complement bit line switch is further configured to selectively couple the complement bit line to the ground rail.

11. The resistive memory device of claim 10, wherein the write circuit is configured to control the bit line switch, the NMOS gate and the complement bit line switch, respectively, to couple the bit line to the power rail, while the NMOS gate is in an ON state and the complement bit line is coupled to the ground rail.

12. The resistive memory device of claim 11, wherein the resistive element and the current source are arranged such when the complement bit line is coupled to the ground rail while the NMOS gate is in an ON state and the bit line is coupled to the power rail the current source injects a forward write current through the bit switch, through the resistive memory element, and through the complement bit line switch to ground.

13. The resistive memory device of claim 12, wherein the resistive memory element has a first magnetization state and a second magnetization state, and wherein the forward write current places the resistive memory element into one of the first and the second magnetization states.

14. The resistive memory device of claim 13, wherein the resistive memory element includes a spin-transfer-torque (STT) magnetic tunnel junction (MTJ) element.

15. The resistive memory device of claim 5 wherein the write circuit includes another constant current source, and wherein the bit line switch is further configured to selectively couple the bit line to the another current source, and the complement bit line switch is further configured to selectively couple the complement bit line to the ground rail.

16. The resistive memory device of claim 15, wherein the write circuit is configured to control the complement bit line switch, the PMOS gate and the bit line switch, respectively, to couple the complement bit line to the current source while the PMOS gate is in an ON state and the bit line is coupled to the ground rail.

17. The resistive memory device of claim 16, wherein the resistive element and the constant current source are arranged such when the complement bit line is coupled to a power source while the PMOS gate is in an ON state and the complement bit line is coupled to the current source the current source injects a reverse write current through the complement bit line switch, through the transmission gate, through the resistive memory element, and through the complement bit line switch to ground.

18. The resistive memory device of claim 17, wherein the resistive memory element has a first magnetization state and a second magnetization state, and wherein the reverse write current places the resistive memory element into one of the first and the second magnetization states.

19. The resistive memory device of claim 18, wherein the resistive memory element includes a spin-transfer-torque (STT) magnetic tunnel junction (MTJ) element.

20. The resistive memory device of claim 17 wherein the write circuit is further configured to control the complement bit line switch, the NMOS gate and the complement bite line switch, respectively, to couple the bit line to the another current source while the NMOS gate is in an ON state and the complement bit line is coupled to the ground rail.

21. The resistive memory device of claim 20, wherein the resistive element and the current source are arranged such when the bit line is coupled to the another power source while the NMOS gate is in an ON state and the complement bit line is coupled to the ground rail the another current source injects a forward write current through the bit switch, through the resistive memory element, through the transmission gate and through the complement bit line switch to ground.

22. The resistive memory device of claim 21, wherein the resistive memory element has a first magnetization state and a second magnetization state, and wherein the forward write current places the resistive memory element into one of the first and the second magnetization states.

23. The resistive memory device of claim 22, wherein the resistive memory element includes a spin-transfer-torque (STT) magnetic tunnel junction (MTJ) element.

24. The resistive memory device of claim 1, wherein the memory device is integrated in at least one semiconductor die.

25. The resistive memory of claim 24, further comprising a device, selected from the group consisting of a set top box, music player, video player, entertainment unit, navigation device, communications device, personal digital assistant (PDA), fixed location data unit, and a computer, into which the memory device is integrated.

26. A method for setting a magnetization state of a resistive memory element, comprising:
forward switching a transmission gate to a forward on state;
injecting a forward write current through the transmission gate and the resistive memory element to set a forward magnetization state;
reverse switching the transmission gate to a reverse on state; and
injecting a reverse write current through the transmission gate and the resistive memory element to set a reverse magnetization state.

27. The method of claim 26, wherein transmission gate forward on state has an NMOS pass gate without source loading effect and a PMOS pass gate with source loading effect.

28. The method of claim 26, wherein the transmission gate reverse on state has a PMOS pass gate without source loading effect and an NMOS pass gate with source loading effect.

29. A device for setting a magnetization state of a resistive memory element, comprising:
means for generating a forward write current on a bit line at a given forward current magnitude;
means for selectively injecting the forward write current from the bit line through the resistive memory element to a source line;
means for generating a reverse write current on a source line at a given reverse current magnitude; and
means for selectively injecting the reverse write current from source line through the resistive memory element to the bit line.

30. The device of claim 29,
wherein the injecting the forward write current from the bit line through the resistive memory element to the source line establishes a given forward write voltage on the bit line,
wherein the injecting the reverse write current from the source line through the resistive memory element to the bit line establishes a given reverse write voltage on the source line substantially equal in magnitude to the forward write voltage.

31. The device of claim 30, wherein a magnitude of the reverse write current is approximately equal to a magnitude of the forward write current.

32. The device of claim 29, wherein the device is integrated in at least one semiconductor die.

33. The device of claim 32, further comprising a device, selected from the group consisting of a set top box, music player, video player, entertainment unit, navigation device, communications device, personal digital assistant (PDA), fixed location data unit, and a computer, into which the arrangement is integrated.

34. A communication device comprising:
an antenna;
a wireless controller coupled to the antenna;
an integrated circuit coupled to the wireless controller, having
a processing unit,
a resistive memory coupled to the processing unit, the resistive memory comprising:
a resistive memory bit cell having a resistive memory element coupled to a bit line and a transmission gate configured to selectively couple the resistive memory element to a complement bit line; and
a write circuit having a constant current source, a complement bit line switch to selectively couple the constant current source to the complement bit line and a transmission gate control circuit to control the transmission gate.

35. The communication device of claim 34, wherein the write circuit further comprises a bit line switch configured to selectively couple the bit line to a ground rail.

36. The communication device of claim 34, wherein the transmission gate includes a CMOS device having an NMOS gate in parallel with a PMOS gate.

37. A method for setting a magnetization state of a resistive memory element, comprising:
step for forward switching a transmission gate to a forward on state;
step for injecting a forward write current through the resistive memory element and the transmission gate;
step for reverse switching the transmission gate to a reverse on state; and
step of injecting a reverse write current through the transmission gate and the resistive memory element.

38. The method of claim 37, wherein the transmission gate forward on state has an NMOS pass gate without source loading effect.

39. The method of claim 37, wherein the transmission gate reverse on state has a PMOS pass gate without source loading effect.
